(19) United States
(12) Patent Application Publication
(10) Pub. No.: US 2022/0109006 A1
(43) Pub. Date: Apr. 7, 2022

(54) DISPLAY PANEL AND DISPLAY

(71) Applicant: SHENZHEN ROYOLE TECHNOLOGIES CO., LTD., Shenzhen (CN)

(72) Inventors: Xingling Guo, Shenzhen (CN); Xiaoping Tan, Shenzhen (CN); Xing Liu, Shenzhen (CN)

(21) Appl. No.: 17/428,226

(22) PCT Filed: Feb. 3, 2019
(86) PCT No.: PCT/CN2019/074674

§ 371 Date: Aug. 3, 2021

(51) Int. Cl. H01L 27/12

(52) U.S. Cl. CPC H01L 27/124

(57) ABSTRACT

A display panel and a display comprising the display panel. The display panel comprises a primary display area (190) and a secondary display area (290); a first gate driving unit (121) for display driving is provided in the primary display area (190), and a second gate driving unit (122) for display driving is provided in the secondary display area (290); a via hole (181) is formed in the secondary display area (290); at least a portion of the secondary display area (290) is configured to display an image together with at least a portion of the primary display area (190). The display panel increases the screen-to-body ratio and is more attractive.

### TECHNICAL FIELD

The present application relates to the technical field of display, in particular, to a display panel and a display.

### BACKGROUND ART

On the current market, the screen-to-body ratio of display panels of mobile phone products becomes larger increasingly, with the larger screen-to-body ratio as a trend and fashion. However, due to consumers' function requirements for other aspects of a mobile phone, the front-end hardware, such as the front camera of a mobile phone, various light sensors, a depth-of-field infrared sensor, earpieces and the like on the front of a mobile phone, will occupy the display space of the screen, thereby reducing the screen-to-body ratio.

In order to solve this contradiction, some mobile phones use display panels, such as, “bang screen”, “water drop screen” and so on. This design can increase the screen-to-body ratio of the display panel and leave room for applying various front-end hardware. However, such design is difficult to further increase the screen-to-body ratio of the screen.

### SUMMARY

The technical problem to be solved by the embodiments of the present application is to provide a display panel and a display, which can further increases the screen-to-body ratio of the display panel, and is more beautiful.

In order to solve the above technical problems, an embodiment of the first aspect of the present application provides a display panel, wherein the display panel comprises a primary display area and a secondary display area, the primary display area is provided with a first gate driving unit for display driving, and the secondary display area is provided with a second gate driving unit for display driving, via hole is formed in the secondary display area, and at least a part of the secondary display area is configured to display a picture in combination with at least a part of the primary display area.

An embodiment of the second aspect of the present application provides a display, comprising the display panel above-mentioned.

Implementing the embodiments of the present application has the advantageous effects as follows.

Since the via hole is formed in the secondary display area, at least a part of the secondary display area is configured to display a picture in combination with at least a part of the primary display area. For example, the left side, upper side, and lower side of the via hole are all used for display, or both the left and right sides of the functional area are used for display. With such arrangement, the screen-to-body ratio of the display screen can be greatly improved, and the screen is more beautiful.

### BRIEF DESCRIPTION OF DRAWINGS

In order to more clearly explain the technical solutions in the embodiments of the present application or the prior art, the drawings that need to be used in the description of the embodiments or the prior art will briefly introduced below. Obviously, the drawings in the following description are merely some of embodiments of the present application. For those ordinarily skilled in the art, other drawings can be obtained based on these drawings without inventive effort.

FIG. 1 is a schematic diagram of a display panel according to a first embodiment of the present application;

FIG. 2 is a partial circuit connection diagram of the display panel according to the first embodiment of the present application (scanning books and data lines are omitted);

FIG. 3 is a partial circuit connection diagram of a display panel according to another embodiment of the present application (scanning books and data lines are omitted);

FIG. 4 is a schematic diagram of a display panel according to a second embodiment of the present application;

FIG. 5 is a partial circuit connection diagram of the display panel according to the second embodiment of the present application (scanning books and data lines are omitted);

FIG. 6 is a schematic diagram of a display panel according to a third embodiment of the present application;

FIG. 7 is a partial circuit connection diagram of the display panel according to the third embodiment of the present application (scanning books and data lines are omitted);

FIG. 8 is a partial circuit connection diagram of the display panel according to the fourth embodiment of the present application (scanning books and data lines are omitted);

FIG. 9 is a schematic diagram of a display panel according to a fifth embodiment of the present application;

FIG. 10 is a partial circuit connection diagram of the display panel according to the fifth embodiment of the present application (scanning lines and data lines are omitted);

FIG. 11 is a schematic diagram of a display panel according to a sixth embodiment of the present application;

FIG. 12 is a partial circuit connection diagram of the display panel according to the sixth embodiment of the present application (scanning books and data lines are omitted); and

FIG. 13 is a schematic diagram of a display panel according to a seventh embodiment of the present application.

### REFERENCE SIGNS

110—scanning line; 111—first scanning line; 112—second scanning line; 113—third scanning line; 114—fourth scanning line; 515—fifth scanning line; 121—first gate driving unit; 122—second gate driving unit; 123—third gate driving unit; 124—fourth gate driving unit; 130—data driving unit; 431—first data driving unit; 432—second data driving unit; 433—data distribution unit; 141—timing sequence generating unit; 151, 251, 551, 651—bridge circuit; 153—first binding area; 155—first connection circuit; 356—second connection circuit; 157—first flexible circuit board; 161—first timing sequence generating unit; 162—second timing sequence generating unit; 163—control unit; 170, 370—data line; 371—normal data line; 372—isolated data line; 372a—first data part; 372b—second data part; 181—via hole; 190—primary display area; 191—primary area; 192—primary device area; 290—secondary display area; 291—secondary area; 292—secondary device area.

### DETAILED DESCRIPTION OF EMBODIMENTS

The technical solutions in the embodiments of the present application will be described below clearly and completely in conjunction with the accompanying drawings in the embodiments of the present application. Obviously, the described embodiments are merely a part of the embodiments of the present application, rather than all of them. Based on the embodiments of the present application, all other embodiments obtained by those ordinarily skilled in the art without inventive effort shall fall within the protection scope of the present application.

The terms “comprising” and “having” appearing in the specification, claims and drawings of the present application and any variations thereof are intended to indicate the non-exclusive inclusion. For example, a process, method, system, product, or device that comprises a series of steps or units is not limited to the steps or units which have been included, but optionally it further comprises the steps or units not mentioned, or optionally, it also comprises other steps or units inherent to these processes, methods, products or devices. In addition, the terms “first”, “second”, and “third” are configured to distinguish different objects, but not to describe a specific sequence.

### First Embodiment

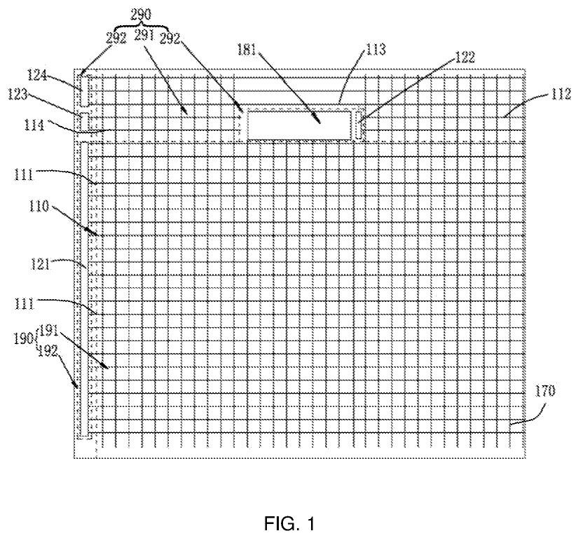

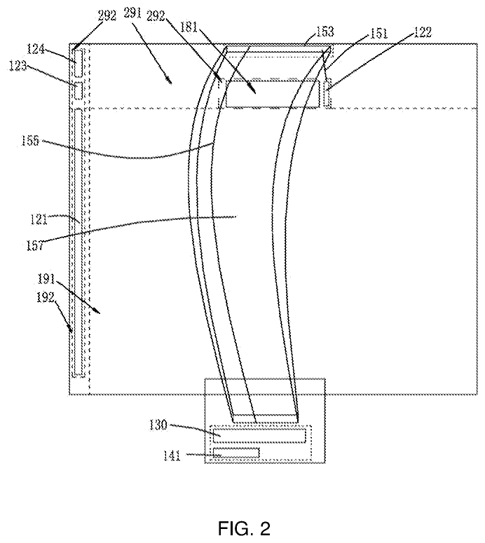

The embodiment of the present application provides a display panel. The display panel is used for display. The display panel can be applied to electronic products, such as mobile phones, tablet computers, and notebook computers. Referring to FIGS. 1 and 2, the display panel comprises a primary display area 190 and a secondary display area 290. The primary display area is provided with a first gate driving unit 121 for display driving. In this embodiment, the primary display area 190 comprises a primary area 191 and a primary device area 192. The primary area 191 is located in the middle of the primary display area 190 and is used for display. The primary device area 192 is located at the edge of the primary display area 190 and is not used for display, but used to, for example, accommodate the first gate driving unit 121. The secondary display area 290 is provided with a second gate driving unit 122 for display driving. In this embodiment, the secondary display area 290 comprises a secondary area 291 and a secondary device area 292. The secondary area 291 is at least partially used for display. The secondary device area 292 is not used for display, but used, for example, to accommodate the second gate driving unit 122. In this embodiment, a via hole 181 is formed in the secondary display area 290, and an electronic device penetrating the display panel is provided in the via hole 181. The electronic device is, for example, an earpiece, a front camera, various sensing sensors, and the like. The number of the via holes 181 may be one, two, three, and so on. In this embodiment, there is one via hole. The via hole 181 is located in the secondary device area 292. In this embodiment, at least a part of the secondary display area 290 is configured to display a picture in combination with at least a part of the primary display area 190. Specifically, the secondary area 291 and the primary area 191 display a picture together.

In this embodiment, the display portion of the secondary display area 290 at least partially surrounds the via hole 181. Since the secondary area 291 of the secondary display area 290 is used for display, the secondary area 291 at least partially surrounds the via hole 181.

In this embodiment, the display panel further comprises a plurality of scanning lines 110, a plurality of data lines 170, and a data driving unit 130.

In this embodiment, the plurality of scanning lines 110 extend laterally from the left side of the display panel to the right side of the display panel, and the plurality of scanning lines 110 are arranged parallel to each other. In this embodiment, the scanning lines 110 comprise first scanning line 111 and second scanning line 112. The first scanning line 111 is located in the primary display area 190, specifically in the primary area 191, and the second scanning line 112 is located in the secondary display area 290, specifically in the secondary area 291 of the secondary display area 290. The second scanning line 112 is adjacent to the first scanning line 111. In this embodiment, the second scanning line 112 has the length smaller than the length of the first scanning line 111, and the second scanning line 112 is located on the upper side of the first scanning line 111. In this embodiment, the second scanning line 112 is located on the right side of the via hole 181. However, the present application is not limited to this. In other embodiments of the present application, the second scanning line may also be located on the left side of the via hole.

In this embodiment, the display panel further comprises a fourth scanning line 114 located in the secondary display area 290. The fourth scanning line 114 and the second scanning line 112 are respectively located on the two opposite sides of the via hole 181 and are separated by the via hole 181. Here, the fourth scanning line 114 is also located on the upper side of the first scanning line 111, and the length of the fourth scanning line 114 is smaller than the length of the first scanning line 111. In this embodiment, the fourth scanning line 114 is located on the left side of the via hole 181. In addition, in other embodiments of the application, when the via hole is located at the upper left corner of the display panel, it is possible to not provide the fourth scanning line in this case. In this embodiment, the fourth scanning lines 114 are in one-to-one correspondence to the second scanning lines 112, that is, there are fourth scanning lines 114 in the number corresponding to the second scanning lines 112, and the four scanning line 114 is located on the extension line to the corresponding second scanning line 112. In this embodiment, the scanning signals received by the fourth scanning line 114 and the second scanning line 112 are the same, that is, the scanning signals received by the fourth scanning line 114 and the second scanning line 112 at the same time point are at the same electrical level.

In this embodiment, the display panel further comprises a third scanning line 113 located in the secondary display area 290. The length of the third scanning line 113 is the same as the length of the first scanning line 111, and the length of the third scanning line 113 is greater than the length of the second scanning line 112 and greater than the length of the fourth scanning line 114. The second scanning line 112, the third scanning line 113, and the fourth scanning line 114 are located in the secondary area 291 of the secondary display area 290. In addition, in other embodiments of the present application, when the via hole is located at the top portion of the display panel, the fourth scanning line may not be provided at this time.

In this embodiment, the plurality of data lines 170 extend longitudinally from the upper side of the display panel to the lower side of the display panel. The plurality of data lines 170 are arranged parallel to each other, and the data lines 170 and the scanning lines 110 are arranged perpendicular to each other. In this embodiment, no data line is provided on the upper side of the via hole 181.

In this embodiment, the first gate driving unit 121 is located on at least one of the left edge and the right edge of the primary display area 190, such as, at the left edge or at the right edge, or both at the left edge and the right edge. In this embodiment, the number of the first gate driving unit 121 is one, which is located at the left edge of the primary display area 190, and the first gate driving unit 121 is electrically connected to the left ends of all the first scanning lines 111, respectively.

In this embodiment, the data driving unit 130 is located at least one of the lower end and the upper end of the display panel, such as, at the upper end or at the lower end, or at both upper and lower ends. In this embodiment, the data driving unit 130 is located at the lower end of the display panel and the data driving unit 130 is electrically connected to the lower ends of all the data lines 170, so that the data signal output by the data driving unit 130 can be transmitted to the data lines 170. Specifically, in this embodiment, the chip on which the data driving unit 130 is located is positioned on the second flexible circuit board. A second binding area is provided at the lower side of the display panel, and the upper end of the second flexible circuit board is bound to the second binding area. The data line 170 is electrically connected to the data driving unit 130 via the second binding area.

In the present application, at least a part of the secondary display area 290 is configured to display a picture in combination with at least a part of the primary display area 190. With such arrangement, the screen-to-body ratio of the display screen can be increased, and the screen is more beautiful. In this embodiment, the left and right sides of the via hole 181 in the secondary display area 290 are both used for display and the upper side of the via hole 181 in the secondary display area 290 is not used for display.

Specifically, in this embodiment, the number of the first gate driving unit 121 is one. The first gate driving unit 121 is located at the left or right edge of the primary display area 190, and as shown in FIG. 1, is located at the left edge of the primary display area 190. The first gate driving unit 121 is electrically connected to the first scanning lines 111 sequentially from top to bottom. The display panel further comprises a third gate driving unit 123. The third gate driving unit 123 is located at the left edge of the secondary display area 290, and the third gate driving unit 123 is located in the secondary device area 292. The third gate driving unit 123 is electrically connected to the left ends of the fourth scanning lines 114 sequentially from top to bottom. Since the second scanning line 112 is located on the right side of the via hole 181, the scanning signal on the third gate driving unit 123 cannot be transmitted to the second scanning line 112. In order to solve this technical problem, in this embodiment, the third gate driving unit 123 and the second gate driving unit 122 are located on the two opposite sides of the via hole 181, that is, the via hole 181 is located between the third gate driving unit 123 and the second gate driving unit 122. In this embodiment, the second gate driving unit 122 is located on the right side of the via hole 181. Here, the second gate driving unit 122 is provided adjacent to the via hole 181. The second gate driving unit 122, with respect to the third gate driving unit 123, is closer to the via hole, and the right side of the second gate driving unit 122 is electrically connected to the second scanning line. Thus, the second scanning line 112 can receive a scanning signal through the second gate driving unit 122. In addition, in other embodiments of the present application, the second gate driving unit may be arranged as not adjacent to the via hole. In this case, the second gate driving unit is located at the right edge of the secondary display area. Moreover, since the data line 170 extends longitudinally, the via hole 181 does not separate the data lines 170 located on the left and right sides thereof. Therefore, the signal of the data driving unit 130 can reach the left and right sides of the via hole 181, such that both the secondary display areas 291 on the left and right sides of the via hole 181 can be used for display, which is beneficial to increase the screen-to-body ratio of the display panel, and the overall display panel is more beautiful.

In this embodiment, the display panel further comprises a fourth gate driving unit 124. The fourth gate driving unit 124 is located at the left edge of the secondary display area 290, and the fourth gate driving unit 124 is located at the upper side of the three gate driving unit 123, and the fourth gate driving unit 124 is located in the secondary device area 292. The fourth gate driving unit 124 is electrically connected to the left ends of the third scanning lines 113 from top to bottom sequentially. In addition, in other embodiments of the present application, the fourth gate driving unit may be located at the right edge of the secondary display area as well. In this embodiment, the third gate driving unit 123, the fourth gate driving unit 124 and the first gate driving unit 121 are located on the same circuit board or in the same chip (in the figure, indicated by the dashed box).

In this embodiment, the first gate driving unit 121 is a GOA (Gate Driver on Array) circuit. The first gate driving unit 121 comprises a plurality of cascaded first GOA units, wherein the plurality of first GOA units extend from the upper side to the lower side of the primary display area 190, and each first GOA unit is electrically connected to the left end of one first scanning line 111, so that the scanning signal on the first GOA unit can be sent to the first scanning line 111. The second gate driving unit 122 is also a GOA circuit. The second gate driving unit 122 comprises a plurality of cascaded second GOA units, and the plurality of second GOA units extend longitudinally from the upper right side of the via hole 181 to the lower right side of the via hole 181. The second GOA unit is electrically connected to the left end of the second scanning line 112, so that the scanning signal on the second GOA unit can be sent to the second scanning line 112. The third gate driving unit 123 is a GOA circuit, and the third gate driving unit 123 comprises a plurality of cascaded third GOA units. The third GOA unit is electrically connected to the left end of the fourth scanning line 114. The fourth gate driving unit 124 is a GOA circuit, and the fourth gate driving unit 124 comprises a plurality of cascaded fourth GOA units. The fourth GOA unit is electrically connected to the left end of the third scanning line 113. In addition, in other embodiments of the present application, the first gate driving unit to the fourth gate driving unit may not be a GOA circuit, but may also be a conventional gate driver. In addition, in other embodiments of the present application, the first gate driving unit, the third gate driving unit, and the fourth gate driving unit are conventional gate drivers, and the second gate driving unit is GOA circuit.

In order to make the second gate driving unit 122 work normally, in this embodiment, the uppermost second GOA unit is electrically connected to the adjacent third scanning line 113 (see FIG. 1, at this time, the scanning lines are driven from top to bottom sequentially), or the lowermost second GOA unit is electrically connected to the adjacent first scanning line 111 (at this time, the scanning lines are driven sequentially from bottom to top), so as to receive scanning signals, thereby driving the second gate driving unit 122. Specifically, in this embodiment, the number of the third scanning line 113 is at least one. When the scanning lines 110 are driven sequentially from top to bottom, the uppermost second GOA unit is electrically connected with the adjacent third scanning line 113 (see FIG. 1), so as to drive the uppermost second GOA unit to work, and the subsequent second GOA units can work normally according to the scanning signal on the previous second scanning line 112; and when the scanning lines 110 are driven from bottom to top sequentially, the lowermost second GOA unit is electrically connected to the adjacent first scanning line 111, so as to drive the lowermost second GOA unit to work. The subsequent second GOA units can also work normally according to the scanning signal on the second scanning line 112 below.

In this embodiment, the uppermost third GOA unit receives the scanning signal from the adjacent third scanning line 113, and the uppermost first GOA unit receives the scanning signal from the adjacent fourth scanning line 114. Alternatively, the lowermost third GOA unit receives the scanning signal from the adjacent first scanning line 111, and the lowermost fourth GOA unit receives the scanning signal from the adjacent fourth scanning line 114.

In this embodiment, the uppermost GOA unit of the second gate driving unit 122 and the uppermost GOA unit of the third gate driving unit 123 receive scanning signals from the same adjacent third scanning line 113, that is, the uppermost second GOA unit and the uppermost third GOA unit receive scanning signals from the same adjacent third scanning line 113. Alternatively, the lowermost GOA unit of the second gate driving unit 122 and the lowermost GOA unit of the third gate driving unit 123 receive scanning signals from the same adjacent first scanning line 111.

In this embodiment, the second gate driving unit 122 also needs a timing sequence signal to output the scanning signal to the second scanning line 112. In order for the second gate driving unit 122 to obtain the timing sequence signal, referring to FIG. 2, in this embodiment, the display panel further comprises a timing sequence generating unit 141, a first connection circuit 155, and a bridge circuit 151. The timing sequence generating unit 141 is disposed adjacent to the data driving unit 130, and the timing sequence generating unit 141 is electrically connected to the first gate driving unit 121 and the data driving unit 130, respectively. The timing sequence generating unit 141 is also directly or indirectly electrically connected to the lower end of the first connection circuit 155, and the upper end of the first connection circuit 155 is connected to the first binding area 153 at the upper side of the display panel. One end of the bridge circuit 151 is electrically connected to the first binding area 153, and the other end thereof is electrically connected to the second gate driving unit 122. Here, the bridge circuit 151 comprises one wire or a plurality of wires. Therefore, the timing sequence signal output by the timing sequence generating unit 141 is transmitted to the second gate driving unit 122 via the first connection circuit 155 and the bridge circuit 151, so that the second gate driving unit 122 can normally output the scanning signal to the second scanning line 112. In this embodiment, the first connection circuit 155 is located on the first flexible circuit board 157. The first gate driving unit 121, the third gate driving unit 123, and the fourth gate driving unit 124 are located at the edge of the display panel, and they receive timing sequence signals in the manner of conventional technology in the art, which will not be repeated here.

In this embodiment, the data driving unit 130 and the timing sequence generating unit 141 are located on one chip, and the chip is located on a second flexible circuit board (not marked in the figure). In addition, in other embodiments of the present application, the data driving unit and the timing sequence generating unit may also be located on different chips.

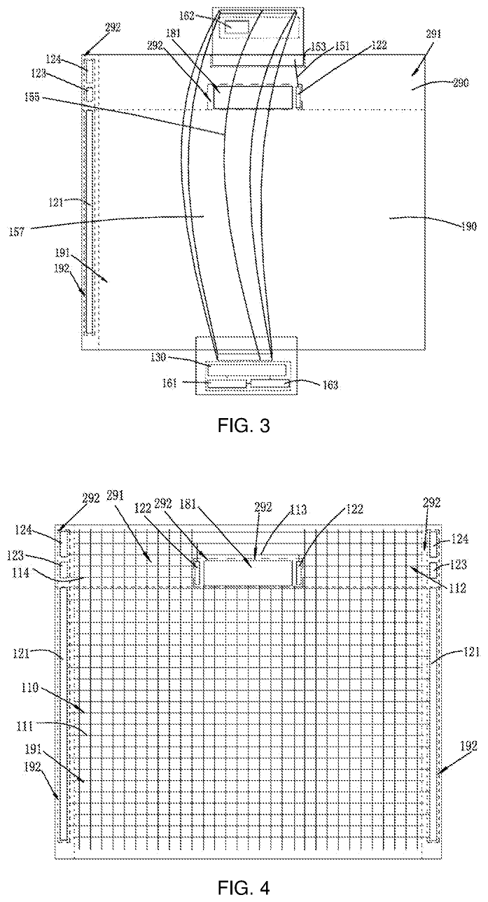

In addition, in other embodiments of the present application, referring to FIG. 3, the display panel further comprises a control unit 163, a first timing sequence generating unit 161, a second timing sequence generating unit 162, a first connection circuit 155 and a bridge circuit 151. The first timing sequence generating unit 161 and the second timing sequence generating unit 162 are respectively located at the lower end and the upper end of the display panel. The control unit 163 and the first timing sequence generating unit 161 are respectively disposed adjacent to the data driving unit 130. The first timing sequence generating unit 161 is electrically connected to the control unit 163. The first timing sequence generating unit 161 is electrically connected to the data driving unit 130 and the first gate driving unit 121, respectively. Both ends of the first connection circuit 155 are electrically connected to the control unit 163 and the second timing sequence generating unit 162, respectively, and the second timing sequence generating unit 162 is electrically connected to the second gate driver via the bridge circuit 151. Therefore, the control unit 163 outputs the control signal, which is output to the second timing sequence generating unit 162 via the first connection circuit 155, and the second timing sequence generating unit 162 generates the timing sequence signal, which is transmitted to the second gate driving unit 122 via the bridge circuit 151, so that the second gate driving unit 122 can normally output a scanning signal to the second scanning line 112. Here, the data driving unit 130, the control unit 163, and the first timing sequence generating unit 161 are located on one chip, and the second timing sequence generating unit 162 is located on another chip. In addition, in other embodiments of the present application, the data driving unit, the control unit, and the first timing sequence generating unit may also be located on different chips. In this embodiment, the second timing sequence generating unit 162 is located on a third flexible circuit board (not marked in the figure), and the third flexible circuit board is bound to the first binding area 153 at the upper side of the display panel.

In addition, an embodiment of the present application also provides a display, which comprises the display panel above-mentioned.

### Second Embodiment

FIG. 4 is a schematic diagram of a display panel according to a second embodiment of the present application. The schematic diagram of FIG. 4 is similar to that of FIG. 1. Therefore, a same reference number represents the same component, which will not be repeated here. The main difference between this embodiment and the first embodiment is that the numbers of the first gate driving unit to the fourth gate driving unit are all two.

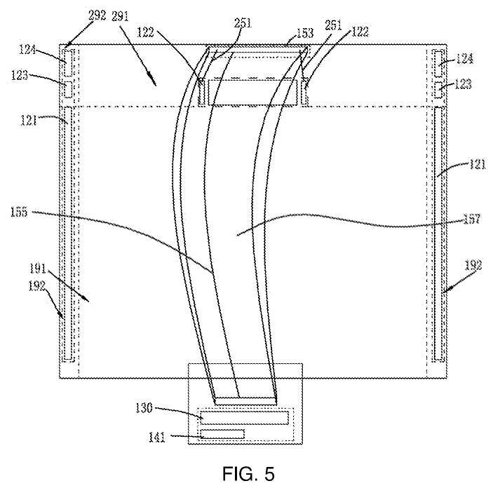

Referring to FIGS. 4 and 5, in this embodiment, the number of the first gate driving units 121 is two, wherein the two first gate driving units 121 are respectively located at the left edge and the right edge of the primary display area 190. The two first gate driving units 121 are both GOA circuits, and the two first gate driving units 121 are alternately connected to the first scanning lines 111 in sequence. Specifically, the first gate driving unit 121 on the left side is electrically connected to the first scanning lines 111 numbered as an odd number, and the first gate driving unit 121 on the right side is electrically connected to the first scanning lines 111 numbered as an even number, that is, one first gate driving unit 121 is electrically connected to half or nearly half of the first scanning lines 111.

The number of the fourth gate driving unit 124 is two, and the two fourth gate driving units are respectively located at the left and right edges of the secondary display area 290, and both fourth gate driving units 124 are the GOA circuit. The two fourth gate driving units 124 are alternately connected to the third scanning lines 113 in sequence. Specifically, the fourth gate driving unit 124 on the left side is electrically connected to the third scanning lines 113 numbered as an odd number, and the fourth gate driving unit 124 on the right side is electrically connected to the third scanning lines 113 numbered as an even number.

The number of the second gate driving units 122 is two, and the two second gate driving units 122 are respectively located on the left and right sides of the via hole 181 and provided adjacent to the via hole 181. Here, the two second gate driving units 122 are located in the secondary device area 292. The number of the third gate driving units 123 is two, and the two third gate driving units 123 are respectively located at the left and right edges of the secondary display area 290. Both of the two third gate driving units 123 are GOA circuits. In this embodiment, the third gate driving unit 123 and the second gate driving unit 122 located on one side of the via hole 181 are alternately electrically connected to the fourth scanning lines 114 in sequence, and the third gate driving unit 123 and the second gate driving unit 122 located on the other side of the via hole are alternately electrically connected to the second scanning lines 112 in sequence.

In this embodiment, the first gate driving unit 121 comprises a plurality of cascaded first GOA units, the second gate driving unit 122 comprises a plurality of cascaded second GOA units, and the third gate driving unit 123 comprises a plurality of cascaded third GOA units. The third GOA units and the second GOA units located on the left side of the via hole 181 are alternately electrically connected to the fourth scanning lines 114 in sequence, and the third GOA units and the second GOA units located on the right side of the via hole 181 are alternately electrically connected to the second scanning lines 112 in sequence. The uppermost second GOA units of the two second gate driving units 122 are respectively electrically connected to two adjacent third scanning lines 113 (wherein the scanning lines are driven from top to bottom). The uppermost third GOA units of the two third gate driving units 123 is electrically connected to two adjacent third scanning lines 113, respectively. It can be understood that, in other embodiments, the lowermost second GOA units of the two second gate driving units are electrically connected to two adjacent first scanning lines, respectively (wherein the scanning lines are driven from bottom to top). The lowermost third GOA units of the two third gate driving units is respectively electrically connected to two adjacent first scanning lines.

Specifically, in this embodiment, two second scanning lines 112 and two fourth scanning lines 114 are briefly shown in FIG. 4. Of course, more second scanning lines 112 and fourth scanning lines 114 are also possible. Counting from top to bottom, the first one of the second scanning lines 112 is electrically connected to the third gate driving unit 123 on the right side. The second gate driving unit 122 on the right side of the via hole 181 is electrically connected to the second one of the second scanning lines 112. The second gate driving unit 122 on the left side of the via hole 181 is electrically connected to the first one of the fourth scanning lines 114, and the first gate driving unit 121 on the left side is electrically connected to the second one of the fourth scanning lines 114. The next ones of the second scanning lines 112 and fourth scanning lines 114, if any, are electrically connected to the third gate driving unit 123 and the second gate driving unit 122, in the same way as the first one of the second scanning lines 112, the second one of the second scanning lines 112, the first one of the fourth scanning lines 114, and the second one of the fourth scanning lines 114. In this embodiment, the uppermost second GOA unit on the right side of the via hole 181 is electrically connected to the last one of the third scanning lines 113. The uppermost second GOA unit on the left side of the via hole 181 is electrically connected to the penultimate third scanning line 113. In addition, in other embodiments of the present application, counting from top to bottom, when the first one of the fourth scanning lines is electrically connected to the third gate driving unit on the left side, the second gate driving unit on the left side of the via hole is electrically connected to the second one of the fourth scanning lines, and the second gate driving unit on the right side of the via hole is electrically connected to the first one the second scanning lines. The third gate driving unit on the right side is electrically connected to the second one of the second scanning lines. The next ones of second scanning lines and fourth scanning lines, if any, are electrically connected to the third gate driving unit and the second gate driving unit by means of the first one of the second scanning lines, the second one of the second scanning lines, the first one of the fourth scanning lines, and the second one of the fourth scanning lines. Here, the uppermost second GOA unit on the right side of the via hole is electrically connected to the penultimate third scanning line, and the uppermost second GOA unit on the left side of the via hole is electrically connected to the last one of the third scanning lines. In addition, when the lowermost second GOA units of the two second gate driving units 122 are respectively electrically connected to the two adjacent first scanning lines 111, the lowermost second GOA units of the two second gate driving units 122 have a similar connecting manner with the above. Similarly, in this embodiment, the uppermost third GOA unit on the left side of the via hole 181 is electrically connected to the last one of the third scanning lines 113, and the uppermost third GOA unit on the right side of the via hole 181 is electrically connected to the penultimate third scanning line 113.

In this embodiment, the second gate driving unit 122 also needs timing sequence signals to output normal scanning signals to the fourth scanning lines 114 and the second scanning lines 112. In order for the second gate driving unit 122 to obtain timing sequence signals and other control signals, referring to FIG. 5, in this embodiment, the display panel further comprises a timing sequence generating unit 141, a first connection circuit 155, and a bridge circuit 251. The timing sequence generating unit 141 is disposed adjacent to the data driving unit 130. The timing sequence generating unit 141 is electrically connected to the first gate driving unit 121 and the data driving unit 130, respectively, and the timing sequence generating unit 141 is also directly or indirectly electrically connected to the lower end of the first connection circuit 155. The upper end of the first connection circuit 155 is connected to the first binding area 153 on the upper side of the display panel. In this embodiment, the number of bridge circuits 251 is two. The upper ends of the two bridge circuits 251 are electrically connected to the first binding area 153. The lower ends of the two bridge circuits 251 are electrically connected to the two second gate driving units 122, respectively. Therefore, the timing sequence signal output by the timing sequence generating unit 141 is transmitted to the two second gate driving units 122 via the first connection circuit 155 and the bridge circuits 251, so that the second gate driving units 122 can normally output scan signals to the fourth scanning lines 114 and second scanning lines 112.

In addition, in other embodiments of the present application, similar to FIG. 3, the display panel further comprises a control unit, a first timing sequence generating unit, a second timing sequence generating unit, a first connection circuit and a bridge circuit, which will not be repeated here. The control unit outputs a control signal, which is transmitted to the second timing sequence generating unit via the first connection circuit, and the second timing sequence generating unit generates timing sequence signals that are respectively transmitted to the second gate driving units via the bridge circuits, so that the second gate driving units can normally output the scanning signals to the fourth scanning lines and the second scanning lines. Here, the data driving unit, the control unit, and the first timing sequence generating unit are located on one chip. In addition, in other embodiments of the present application, the data driving unit, the control unit, and the first timing sequence generating unit may also be located on different chips.

### Third Embodiment

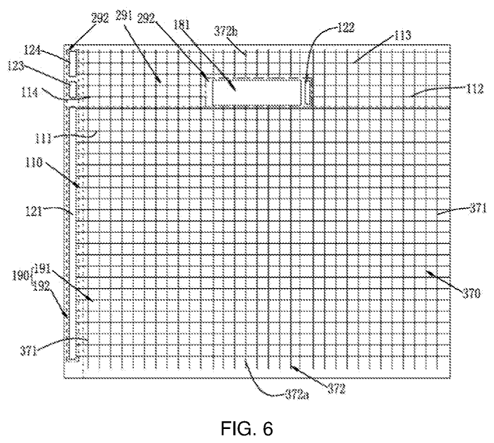

FIG. 6 is a schematic diagram of a display panel according to a third embodiment of the present application. The schematic diagram of FIG. 6 is similar to that of FIG. 1. Therefore, the same reference number indicates the same component, which will not repeated here. The main difference between this embodiment and the first embodiment is that the periphery (four sides) of the via hole is used for display.

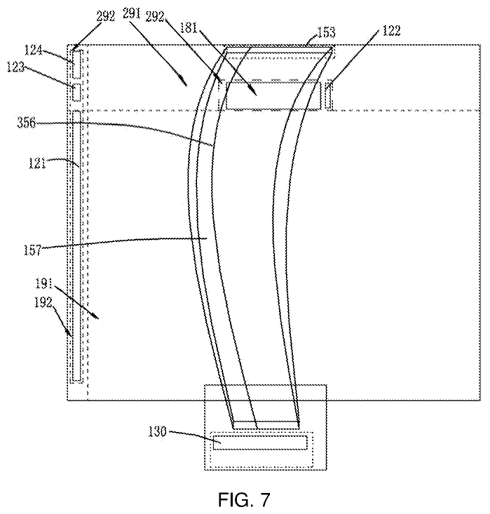

Referring to FIGS. 6 and 7, in this embodiment, the data lines 370 comprise an isolated data line 372 and a normal data line 371. The normal data line 371 which is continuous and uninterrupted, extends from the lower side of the display panel to the upper side of the display panel. The isolated data line 372 extends from the lower side of the display panel to the upper side of the display panel, wherein the isolated data line is interrupted. Specifically, it is separated into two parts at the via hole 181. In this embodiment, the isolated data line 372 includes a first data part 372a and a second data part 372b. In this embodiment, the first data part 372a is located on the lower side of the via hole 181, and the second data part 372b is located on the upper side of the via hole 181, and vice versa of course.

In this embodiment, the data driving unit 130 is located at the lower end of the display panel. The data driving unit 130 is electrically connected to the lower end of the normal data line 371 and the lower end of the first data part 372a, so that the normal data line 371 and the first data part 372a can obtain the data signal transmitted by the data driving unit 130. Since the second data part 372b is located on the upper side of the via hole 181 of the display panel, the signal transmitted from the data driving unit 130 cannot be transmitted to the second data part 372b, such that the display panel portion on the upper side of the functional area 380 cannot be used for display. In order to solve this technical problem, referring to FIG. 7, in this embodiment, the display panel comprises a second connection circuit 356, the lower end of the second connection circuit 356 is electrically connected to the data driving unit 130, and the upper end of the second connection circuit 356 is connected to the first binding area 153 on the upper side of the display panel. The upper end of the second data part 372b is electrically connected to the second connection circuit 356 via the first binding area 153. Thus, the second data part 372b may be electrically connected to the data driving unit 130 via the first binding area 153 and the second connection circuit 356, so that the data signal output by the data driving unit 130 may be transmitted to the second data part 372b. Moreover, since the normal scanning lines 111 can be arranged in the area above the functional area 180, the area above the functional area 180 can be used for normal display, such that the screen-to-body ratio of the display panel can be increased. In this embodiment, the second connection circuit 356 is located on the first flexible circuit board 157. Of course, in other embodiments of the present application, it is possible that the second connection circuit is not located on the first flexible circuit board.

### Fourth Embodiment

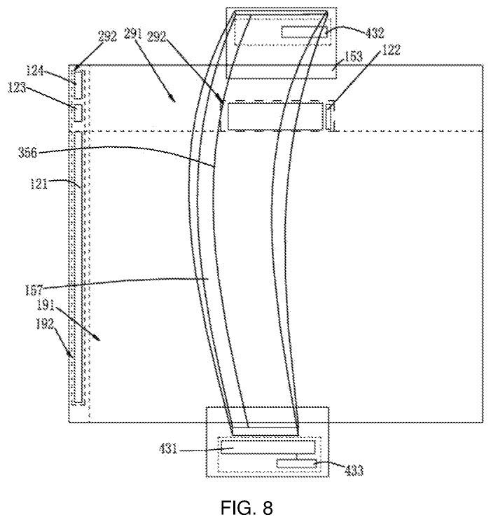

FIG. 8 is a partial circuit connection diagram of the display panel according to the fourth embodiment of the present application. The circuit connection diagram of FIG. 8 is similar to the circuit connection diagram of FIG. 7. Therefore, the same reference number represents the same component, which will not be repeated here. The main difference between this embodiment and the third embodiment is the data driving unit.

Referring to FIG. 8, in this embodiment, the data driving unit comprises a first data driving unit 431 and a second data driving unit 432. The first data driving unit 431 is located at the lower end of the display panel. The second data driving unit 432 is located at the upper end of the display panel. The first data driving unit 431 is electrically connected to the normal data line 371 and the first data part 372a, and the second data driving unit 432 is electrically connected to the second data part 372b. The display panel further comprises a data distribution unit 433 and a second connection circuit 356. The data distribution unit 433 is electrically connected to the first data driving unit 431 and the second data driving unit 432, respectively, and the data distribution unit 433 is disposed adjacent to the first data driving unit 431 and electrically connected to the first data driving unit 431, and the data distribution unit 433 and the second data driving unit 432 are electrically connected with each other through a second connection circuit 356. Thus, the data distribution unit 433 distributes the received data signals to the first data driving unit 431 and the second data driving unit 432, so that the first data driving unit 431 and the second data driving unit 432 can correctly transmit the data signals to the data lines 370.

In this embodiment, the first data driving unit 431 and the data distribution unit 433 are located in one chip, the second data driving unit 432 is located in another chip, and the two chips are located on two different flexible circuit boards, respectively.

### Fifth Embodiment

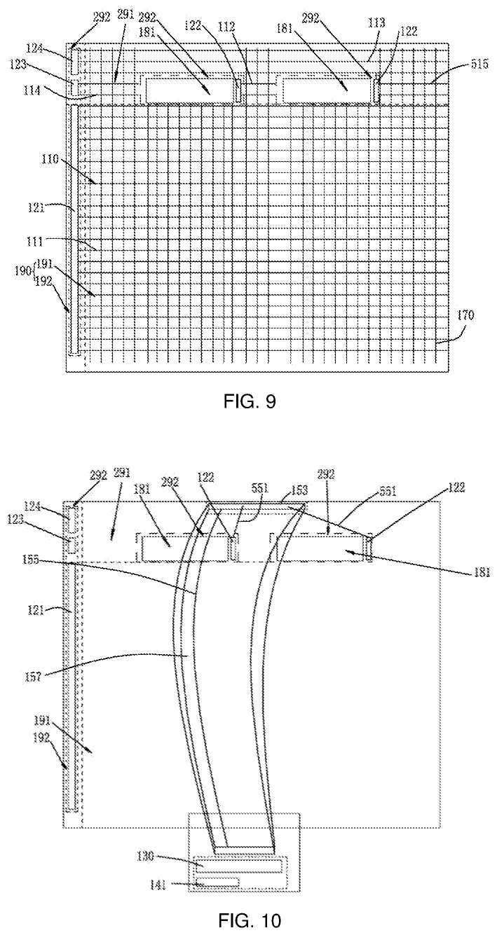

FIG. 9 is a schematic diagram of a display panel according to a fifth embodiment of the present application. The schematic diagram of FIG. 9 is similar to the schematic diagram of FIG. 1. Thus, the same reference number represents the same component, which are not repeated here. The main difference between this embodiment and the first embodiment is the number of via holes.

Referring to FIGS. 9 and 10, in this embodiment, the number of via holes is two, and the two via holes are arranged side by side in the lateral direction. The area on the left side of the left via hole, the area between the two via holes, and the area on the right side of the right via hole are all used for display.

In this embodiment, the scanning lines 110 comprise a first scanning line 111, a second scanning line 112, a third scanning line 113, a fourth scanning line 114, and a fifth scanning line 515, wherein the fourth scanning line 114, the second scanning line 112 and the fifth scanning line 515 are respectively separated by the two via holes 181. In this embodiment, the fourth scanning line 114 is located on the left side of the left via hole 181, and the fifth scanning line 515 is located on the right side of the right via hole 181. The second scanning line 112 is located in the area between the two via holes 181.

In this embodiment, the number of the first gate driving unit 121, the number of the third gate driving unit 123, and the number of the fourth gate driving unit 124 are one, respectively. The first gate driving unit 121, the third gate driving unit 123, and the fourth gate driving unit 124 are located at the left edge or the right edge of the display panel. In FIG. 9, they are located at the left edge of the display panel. The fourth gate driving unit 124 is electrically connected, from top to bottom in sequence, to the third scanning lines 113. The third gate driving unit 123 is electrically connected to the fourth scanning lines 114 from top to bottom in sequence, and the first gate driving unit 121 is electrically connected to first scanning lines 111 from top to bottom in sequence.

In this embodiment, the number of the second gate driving units 122 is two. The two second gate driving units 122 are respectively disposed adjacent to different via holes, wherein one of the second gate driving units 122 is located between the two via holes 181, and the other second gate driving unit 122 and the third gate driving unit 123 are located on the two opposite sides of the two via holes 181. In this embodiment, the other second gate driving unit 122 is located on the right side of the right via hole 181 and adjacent thereto. The two second gate driving units 122 are electrically connected to the second scanning line 112 and the fifth scanning line 515, respectively. Therefore, the second scanning line 112 may obtain a scanning signal through one of the second gate driving units 122, and the fifth scanning line 515 may obtain a scanning signal through the remaining one of the second gate driving units 122.

In this embodiment, the third gate driving unit 121 comprises a plurality of cascaded third GOA units, wherein each third GOA unit is electrically connected to a corresponding fourth scanning line 114. The second gate driving unit 122 comprises a plurality of cascaded second GOA units, wherein the second GOA units of the two second gate driving units 122 are electrically connected to the corresponding second scanning lines 112 and the fifth scanning lines 515, respectively. In this embodiment, the two uppermost second GOA units are electrically connected to the adjacent third scanning lines 113 (wherein scanning lines are driven from top to bottom), or the two lowermost second GOA units are electrically connected to the adjacent first scanning lines 111 (wherein the scanning lines are driven from bottom to top).

Referring to FIG. 10, in this embodiment, the number of the bridge circuits 551 is two, wherein the lower ends of the two bridge circuits 551 are electrically connected to the two second gate driving units 122, respectively. In addition, the related description of the first embodiment may be referred to for how the bridge circuit 551 and the timing sequence generating unit 141 are connected.

### Sixth Embodiment

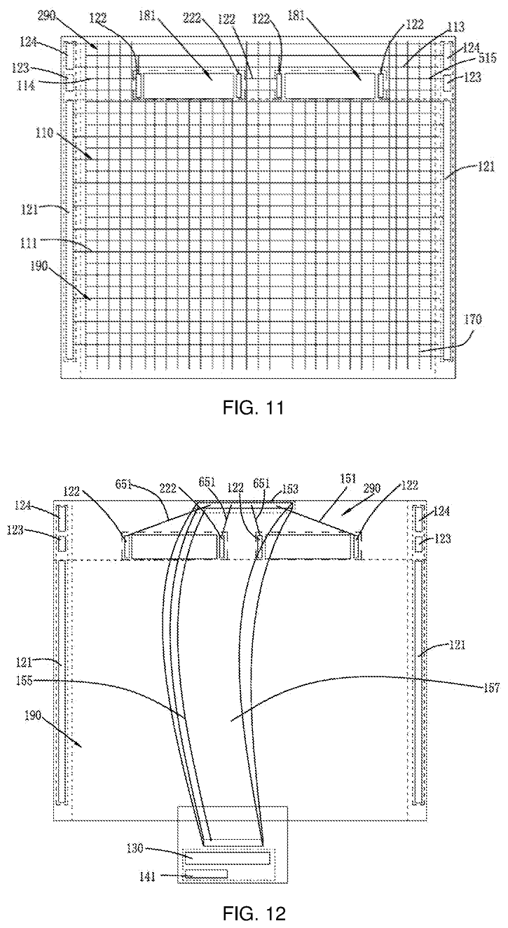

FIG. 11 is a schematic diagram of a display panel according to a sixth embodiment of the present application. The schematic diagram of FIG. 11 is similar to the schematic diagram of FIG. 4, and therefore, the same reference number represents the same component, which will not be repeated here. The main difference between this embodiment and the second embodiment is the number of functional areas.

Referring to FIGS. 11 and 12, in this embodiment, the number of the via holes 181 is two, and the two via holes 181 are arranged side by side in the lateral direction. In the secondary display area 290, the area of the left side of the left via hole 181, the area between the two via holes 181, and the area of the right side of the right via hole 181 are all used for display.

In this embodiment, the scanning line 110 comprises a first scanning line 111, a second scanning line 112, a third scanning line 113, a fourth scanning line 114, and a fifth scanning line 515, wherein the fourth scanning line 114, the second scanning line 112 and the fifth scanning line 515 are separated by two via holes 181, respectively. In this embodiment, the fourth scanning line 114 is located on the left side of the left via hole 181, the fifth scanning line 515 is located on the right side of the right via hole 181, and the second scanning line 112 is located in the area between the two via holes 181.

In this embodiment, the number of the third gate driving units 123 is two, and the two third gate driving units 123 are respectively located at the left and right edges of the secondary display area 290. The third gate driving unit 123 on the left side is electrically connected to the fourth scanning lines 114 numbered as an even number, and the third gate driving unit 123 on the right side is electrically connected to the fifth scanning lines 515 numbered as an odd number, or vice versa. Thus, the third gate driving unit 123 on the left side is electrically connected to half or nearly half of the fourth scanning lines 114, and the third gate driving unit 123 on the right side is electrically connected to half or nearly half of the fifth scanning lines 515.

In this embodiment, the number of the second gate driving units 122 is four, wherein two of the second gate driving units 122 are respectively located on the left side of the left via hole 181 and the right side of the right via hole 181, and the remaining two second gate driving units 122 are located between the two via holes 181. In this embodiment, the fourth scanning lines 114 located on the left side of the left via hole 181 are alternately electrically connected to the fourth gate driving unit 124 and the second gate driving unit 122 on the left side in sequence. The fifth scanning lines 515 located on the right side of the right via hole 181 are alternately electrically connected to the fourth gate driving unit 124 and the second gate driving unit 122 on the right side in sequence. The second scanning lines 112 located between the two via holes 181 are respectively electrically connected to the second gate driving units 122 located between the two via holes 181.

In this embodiment, the third gate driving unit 123 includes a plurality of cascaded third GOA units. The second gate driving unit 122 includes a plurality of cascaded second GOA units. The third GOA units and the second GOA units located on the left side of the left via hole 181 are alternately electrically connected to the fourth scanning lines 114 in sequence. The third GOA units and the second GOA units located on the right side of the right via hole 181 are alternately electrically connected to the fifth scanning lines 515 in sequence. The second GOA units of the two second gate driving units 122 located between the two via holes 181 are alternately electrically connected to the second scanning lines 112 in sequence. The uppermost second GOA units of the second gate driving unit 122 located on the left side of the left via hole 181 and the second gate driving unit 122 located on the right side of the right via hole 181 respectively are connected to the two adjacent third scanning lines 113 (wherein scanning lines are driven from top to bottom). Alternatively, the lowermost second GOA units of the second gate driving unit 122 located on the left side of the left via hole 181 and the second gate driving unit 122 located on the right side of the right via hole 181 are respectively electrically connected to the two adjacent first scanning lines 111 (wherein the scanning lines are driven from bottom to top). The uppermost second GOA units of the two second gate driving units 122 located between the two via holes 181 are respectively electrically connected to two adjacent third scanning lines 113 (wherein the scanning lines are driven from top to bottom). Alternatively, the lowermost second GOA units of the two second gate driving units 122 located between the two via holes 181 are respectively electrically connected to the two adjacent first scanning lines 111 (wherein the scanning lines are driven from bottom to top).

Specifically, in this embodiment, two second scanning lines 112, two fourth scanning lines 114, and two fifth scanning lines 515 are briefly shown in FIG. 11. Of course, it is possible to provide more second scanning lines 112, fourth scanning lines 114, and the fifth scanning lines 515. Counting from top to bottom, the first one of the fifth scanning lines 515 is electrically connected to the third gate driving unit 123 on the right side. The second one of the fifth scanning lines 515 is electrically connected to the second gate driving unit 122 on the right side of the right via hole 181. The first one of the fourth scanning lines 114 is electrically connected to the second gate driving unit 122 on the left side of the left via hole 181, and the second one of the fourth scanning lines 114 is electrically connected to the third gate driving unit 123 on the left side. The second gate driving units 122 between the two via holes 181 is alternately electrically connected to the second scanning lines 112 in sequence. The next ones of second scanning lines 112, the fourth scanning lines 114, and the fifth scanning lines 515, if any, are electrically connected to the third gate driving unit 123 and the second gate driving unit 122 in the same way as the first ones of the second scanning lines 112, the fourth scanning lines 114 and the fifth scanning lines 515, and the second ones of the second scanning lines 112, the fourth scanning lines 114 and the fifth scanning lines 515. In this embodiment, the uppermost second GOA unit on the right side of the right via hole 181 is electrically connected to the last one of the third scanning lines 113, and the uppermost second GOA unit on the left side of the left via hole 181 is electrically connected to the penultimate third scanning line 113. The uppermost second GOA unit of the two second gate driving units 122 between the two via holes 181, which is electrically connected to the first one of the second scanning lines, is electrically connected to the penultimate third scanning line 113. The uppermost second GOA unit of the two second gate driving units 122 between the two via holes 181, which is electrically connected to the second one of the second scanning lines, is electrically connected to the last one of third scanning lines 113. In addition, in other embodiments of the present application, when the first one of the fourth scanning lines is electrically connected to the third gate driving unit on the left side of the left via hole, the uppermost GOA units of the four second gate driving units are connected with the last one of the third scanning lines and the penultimate third scanning line, with the connection being reversed.

Referring to FIG. 12, in this embodiment, the number of the bridge circuits 651 is four, wherein the lower ends of the four bridge circuits 651 are electrically connected to the four second gate driving units 122, respectively, and the upper ends of the four bridge circuits 651 are electrically connected to the first binding area 153, respectively. In addition, the related description of the second embodiment may be referred to for how to connect the bridge circuit and the timing sequence generating unit 141.

### Seventh Embodiment

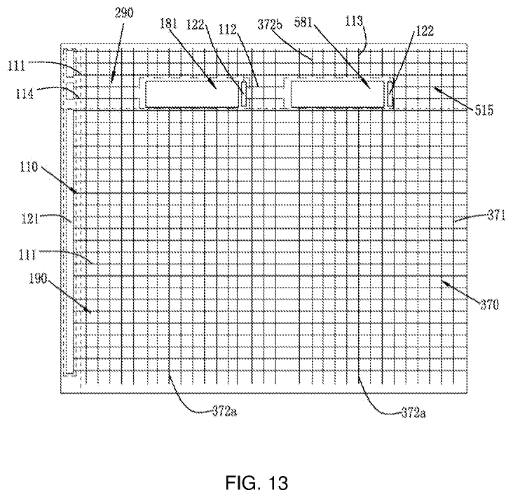

FIG. 13 is a schematic diagram of a display panel according to a seventh embodiment of the present application. The schematic diagram of FIG. 13 is similar to the schematic diagrams of FIGS. 9 and 6. Therefore, the same reference number represents the same component, which will not be repeated here.

Referring to FIG. 13, in this embodiment, the number of via holes 181 is two. In the secondary display area 290, the area between the two via holes 181, the area on the left side of the left via hole 181, the area on the right side of the right via hole 181 and the area on the upper side of the two via holes 181 are all used for display. That is, the periphery of the via holes 181 is all used for display. The scanning lines 110 comprises a first scanning line 111, a second scanning line 112, a third scanning line 113, a fourth scanning line 114, and a fifth scanning line 515, wherein the fourth scanning line 114, the second scanning line 112 and the fifth scanning line 515 are separated by two via holes 181, respectively. The data lines 370 comprise a normal data line 371 and an isolated data line 372. The isolated data line 372 comprises a first data part 372a and a second data part 372b. Basically, this embodiment is obtained by combining the fifth embodiment with the third embodiment, and it will not be repeated here. In this embodiment, the first connection circuit and the second connection circuit are located on the same first flexible circuit board. In addition, in other embodiments of the present application, the fifth embodiment can be combined with the fourth embodiment to obtain a new embodiment. In this case, the first timing sequence generating unit, the control unit, the first data unit, and the data distribution unit are located on the same chip, and the chip is located on one second flexible circuit board. The second timing sequence generating unit and the second data unit are located on the same chip, and the chip is located on another third flexible circuit board. In addition, in other embodiments of the present application, the sixth embodiment can be combined with the third embodiment to obtain a new embodiment. In other embodiments of the present application, the sixth embodiment can be combined with the fourth embodiment to obtain a new embodiment. At this time, the first timing sequence generating unit, the control unit, the first data unit, and the data distribution unit are located in the same chip, and the chip is located on one second flexible circuit board. The second timing sequence generating unit and the second data unit are located on the same chip, and the chip is located on another third flexible circuit board.

It should be noted that the various embodiments in this specification are described in a progressive manner. Each embodiment focuses on the differences from other embodiments. The same and similar parts between the various embodiments may be obtained by referring to each other. As for the device embodiments, since they are basically similar to the method embodiments, the description is relatively simple. The part of the description of the method embodiments may be referred by for the similarity.

The above-disclosed are only the preferred embodiments of the present application, which cannot be used to limit the claimed scope of the present application obviously. Therefore, equivalent changes made according to the claims of the present application still fall within the scope of the present application.

1. A display panel, wherein the display panel comprises a primary display area and a secondary display area, wherein the primary display area is provided with a first gate driving unit for display driving, and the secondary display area is provided with a second gate driving unit for display driving, a via hole is formed in the secondary display area, and at least a part of the secondary display area is configured to display a picture in collaboration with at least a part of the primary display area.

2. The display panel according to claim 1, wherein a display portion of the secondary display area at least partially surrounds the via hole.

3. The display panel according to claim 2, wherein the display panel further comprises first scanning lines located in the primary display area and second scanning lines located in the secondary display area, wherein a length of the second scanning lines is smaller than a length of the first scanning lines.

4. The display panel according to claim 3, wherein the second gate driving unit is connected with the second scanning lines and the second gate driving unit is located close to the via hole, and the first gate driving unit is connected with the first scanning lines.

5. The display panel according to claim 4, wherein the display panel further comprises fourth scanning lines located in the secondary display area, wherein the fourth scanning lines and the second scanning lines are respectively located on two opposite sides of the via hole, and separated by the via hole.

6. The display panel according to claim 5, wherein a length of the fourth scanning lines is smaller than the length of the first scanning lines.

7. The display panel according to claim 5, wherein the fourth scanning lines and the second scanning lines receive same scanning signal.

8. The display panel according to claim 5, wherein the fourth scanning lines are in one-to-one correspondence to the second scanning lines, and the fourth scanning lines are located on extension lines of corresponding second scanning lines.

9. The display panel according to claim 5, wherein the secondary display area is further provided with a third gate driving unit, wherein the fourth scanning lines are electrically connected with the third gate driving unit, and the second gate driving unit and the third gate driving unit are respectively located on two opposite sides of the via hole.

10. The display panel according to claim 9, wherein the second gate driving unit, with respect to the third gate driving unit, is closer to the via hole.

11. The display panel according to claim 9, wherein the display panel further comprises third scanning lines located in the secondary display area, wherein a length of the third scanning lines is greater than the length of the second scanning lines, and the third scanning lines and the first scanning lines are respectively located on the two opposite sides of the via hole, and the third scanning lines are electrically connected with the third gate driving unit.

12. The display panel according to claim 11, wherein the second gate driving unit is a GOA circuit, wherein the GOA circuit comprises cascaded second GOA units, and an uppermost second GOA units receives a scanning signal from an adjacent third scanning line or a lowermost second GOA units receives a scanning signal from an adjacent first scanning line.

13. The display panel according to claim 11, wherein the third gate driving unit is a GOA circuit, wherein the GOA circuit comprises cascaded third GOA units, and an uppermost third GOA units receives a scanning signal from an adjacent third scanning line, the first gate driving unit is a GOA circuit, wherein the GOA circuit comprises cascaded first GOA units, and an uppermost first GOA units receives a scanning signal from an adjacent fourth scanning line; or the third gate driving unit is a GOA circuit, wherein the GOA circuit comprises cascaded third GOA units, and a lowermost third GOA units receives a scanning signal from an adjacent first scanning line, and the first gate driving unit is a GOA circuit, wherein the GOA circuit comprises cascaded first GOA units, and a lowermost first GOA units receives a scanning signal from an adjacent fourth scanning line.

14. The display panel according to claim 11, wherein the second gate driving unit and the third gate driving unit are both GOA circuits, and each of the GOA circuits comprises cascaded GOA units, and an uppermost GOA units of the second gate driving unit and an uppermost GOA units of the third gate driving unit receive scanning signals from a same adjacent third scanning line.

15. The display panel according to claim 11, wherein the second gate driving unit and the third gate driving unit are both GOA circuits, and each of the GOA circuits comprises cascaded GOA units, and a lowermost GOA units of the second gate driving unit and a lowermost GOA units of the third gate driving unit receive scanning signals from a same adjacent first scanning line.

16. The display panel according to claim 1, wherein an electronic device penetrating the display panel is provided in the via hole.

17. The display panel according to claim 11, wherein the display panel comprises two third gate driving units and two second gate driving units, and the two third gate driving units are respectively located at a left edge and a right edge of the secondary display area, and the two second gate driving units, arranged adjacent to the via hole, are respectively located at a left side and a right side of the via hole, wherein a third gate driving unit and a second gate driving unit located on one side of the via hole are alternately electrically connected to the fourth scanning lines in sequence, and the first gate driving unit and a second gate driving unit located on the other side of the via hole are alternately electrically connected to the second scanning lines in sequence.

18. The display panel according to claim 17, wherein the third gate driving units comprise a plurality of cascaded third GOA units, and the second gate driving units comprise a plurality of cascaded second GOA units, wherein third GOA units and second GOA units on one side of the via hole are alternately electrically connected to the fourth scanning lines in sequence, and third GOA units and second GOA units on the other side of the via hole are alternately electrically connected to the second scanning lines in sequence, uppermost second GOA units of the two second gate driving units are electrically connected to two most adjacent third scanning lines, respectively, or lowermost second GOA units of the two second gate driving units are electrically connected to two most adjacent first scanning lines, respectively.

19. The display panel according to claim 11, wherein the via holes are in number of two, and the two via holes are arranged side by side in a lateral direction, the display panel further comprises fifth scanning lines, and the second scanning lines are located between the two via holes, the fourth scanning lines are located on a left side of a left via hole of the two via holes, and the fifth scanning lines are located on a right side of a right via hole of the two via holes.

20-29. (canceled)

30. A display, comprising a display panel, wherein the display panel comprises a primary display area and a secondary display area, wherein the primary display area is provided with a first gate driving unit for display driving, and the secondary display area is provided with a second gate driving unit for display driving, a via hole is formed in the secondary display area, and at least a part of the secondary display area is configured to display a picture in collaboration with at least a part of the primary display area.
